(19) United States
(12) Patent Application Publication
(10) Pub. No.: US 2003/0155658 A1
(43) Pub. Date: Aug. 21, 2003

(54) Semiconductor device

(76) Inventors: Valery Moiseevich Ioffe, Novosibirsk (RU); Askhad Ibragimovich Maksutov, Magnitigorsk (RU)

Correspondence Address: Anton J. Hopen, Smith & Hopen, P.A., 15950 Bay Vista Dr., # 220, Clearwater, FL, 33760, US

(21) Appl. No.: 10/223,827

(22) Filed: Aug. 20, 2002

(30) Foreign Application Priority Data
Nov. 26, 2001 (WO) PCT/RU01/00506

(51) Int. Cl. H01L 23/52

(52) U.S. Cl. 257/776

(57) ABSTRACT

The present invention relates to semiconductor devices.

The invention can find application in microelectronics. The device can appear as a voltage controlled variable capacitor, varicap, transistor, or transmission line.

A semiconductor device comprising insulating layer (5) on one part of whose surfaces a conductor strip (6) is established, while on the other part of the surface thereof a semiconductor layer (1) is formed, having either an electron- or a hole-type conduction and provided with an ohmic contact (11), said layer (1) being coated with a layer (2) forming a p-n junction together with the layer (1) and having another ohmic contact (12); part of insulating layer (14) contacting with the layer (1) being formed of high-ohmic semiconductor due to either contacting area being made of high-ohmic semiconductor or to p-n junction between the insulating layer and the layer (1) the doped profile and the thickness of the layer (1) should meet the condition of a complete depletion of the layer (1) or part of thereof in the majority charge carriers till the breakdown of the p-n junction or of the Schottky barrier upon applying an external bias voltage determined by the following inequality:

d(x,z)

(∫/εs) Ni(x,h,z)hdh−Uk<Ui

0

where Ui—the breakdown voltage of the semiconductor layer (1)

h—the coordinate counted off the metallurgical boundary of the p-n junction or Schottky barrier along the thickness of the layer;

q—an elementary charge;

d(x,z)—the thickness of the layer (1);

Ni(x,h,z)—the ion doping profile in the layer (1)

z, x—the coordinates on the surface of the layer (1);

∈s—the permeability of the layer (1);

Uk—built-in junction potential of the layer (1).

### TECHNICAL FIELD

The present invention relates to semiconductor devices. The proposed device can appear as a voltage-controlled variable capacitor, varicap or transistor. Built around the device may be parametric amplifiers and voltage controlled transmission lines.

### BACKGROUND ART

As to its principle of operation the proposed semiconductor device is closest to varicaps (varactors), i.e. semiconductor devices with voltage-controlled reactance. It is common knowledge (cf. a textbook “Physics of Semiconductor Devices” by S. Sze, V.1, Moscow Mir Publishers, 1984, pp. 80-91, 260-262, 381, 384 (in Russian) that in all the three basic elements of semiconductor electronics (that is, p-n junction, Schottki barrier, and MIS-structure) a semiconductor layer is liable to be formed at a definite polarity of the charge applied, said layer being depleted in majority charge carriers and serving as an analog of a dielectric interlayer in conventional capacitors. The thickness of the depletion layer depends on the bias voltage, whereby the voltage V may control the differential capacitance C of a semiconductor device.

A variable capacitor of the heretofore-known construction is now widespread use (cf., e.g., A reference Guide to High-Frequency Circuitry, by E. Red, Moscow Mir Publishers, 1990, pp. 219-220 (in Russian), which appears as a mechanical device adapted to displace the capacitor plates with respect to each other. An obvious disadvantage of the device resides in sluggishness of mechanical functioning.

A transistor is commonly understood to mean a semiconductor device having three or more leads for applying the control voltage thereto and adapted for amplifying, generating, and converting electric oscillations (cf. Encyclopedic Dictionary, Moscow, Sovetskaya Entsiklopedia Publishers, 1991, p.557). A substantial disadvantage inherent in the now-existing transistors, both field-effect and bipolar ones, consists in that their output power is inversely proportional to the squared frequency thereof, which results from a limitation imposed by the avalanche-breakdown voltage of a rather narrow space-charge region of the p-n junction and by ultimate carrier velocity (cf. S. Sze, op. cit., pp. 178-179).

A semiconductor device of the heretofore-known construction is now in use (cf. V. Ioffe, A. Maksoutov, Patent of the Russian Federation No. 2139599, application No. 96124161 of Jan. 18, 1996) chosen to be the prototype of the invention. Said device comprises a low-conductivity or insulating layer on one surface of which is formed a conducting section (1) while the other face is provided with a hole- or electron-type semiconductor layer with an ohmic contact. A semiconductor or metal layer (2) is provided on the surface of the semiconductor layer and with (1) forms a p-n junction or Schottky barrier with another ohmic contact. The choice of the alloy cross section and thickness of the layer (1) is restricted by the condition that said layer or part of it must be fully depleted by the basic charge carriers until breakdown of the p-n junction and/or the Schottky barrier when the latter is subjected to an external bias:

$$( q / {ε}_{s} ) \cdot {\int }_{0}^{d ( x , z )} Ni ( x , y , z ) y ⅆ y - Uk < Ui$$

Where Ui—the breakdown voltage of the semiconductor layer (1);

y—the coordinate counted off the metallurgical boundary of the p-n junction or Schottky barrier along the thickness of the layer (1);

q—an elementary charge;

d(x,z)—the thickness of the layer 1;

Ni(x,y,z)—dopant profile in the layer (1);

z, x—the coordinates on the surface of the layer (1);

∈ₛ—permeability of the layer (1);

Uk—built-in junction potential of the layer (1).

A disadvantage of the device is a limited control in response to a change in the control voltage in a wide range, the value of the capacitance of a capacitor established between the conductor layer, an insulation (dielectric) or a low-conductivity (semiconductor) layer being formed there between, as well as a limited control of a wide range of the resistance value of the low-conductivity layer.

### DISCLOSURE OF THE INVENTION

The present invention has for is primary object to provide a unique semiconductor device adapted to control, in response to a change in the control voltage, the value of the capacitance of a capacitor in a wide range, said capacitor established between conductor plates, an insulation (dielectric) or a low conductivity (semiconductor) layer being formed there between, as well as to control a wide range of the resistance value of the low-conductivity (semiconductor) layer.

The foregoing object is accomplished due to the fact that a semiconductor device, comprising a insulating layer (5) on one of its surfaces a conductor area (6) is established, while the other surface thereof a semiconductor layer (1) is formed having either an electron- or hole-type conduction and provided with an ohmic contact (11), said layer (1) carrying a layer (2) which is made of metal or semiconductor having the type of conduction junction opposite to that of the layer (1), said layer (2) forming a p-n junction together with the layer (1) and having another ohmic contact (12); a part of insulating layer (14) contacting with the first semiconductor layer is made of highly-ohmic semiconductor due to either the fact that the contact layer is made of highly-ohmic semiconductor material or p-n junction being formed between the insulating layer and the semiconductor one; the dopant profile and the thickness of the layer (1) should meet the condition of a complete depletion of the layer (1) or part thereof in the majority charge carriers till the breakdown of the p-n junction or of the Schottky barrier upon applying thereto an external bias voltage determined by the following inequality:

$${\int }_{0}^{d ( x , z )} ( q / {ε }_{s} ) Ni ( x , h , z ) h ⅆ h - Uk < Ui$$

Where Ui—the breakdown voltage of the semiconductor layer (1)

h—the coordinate counted off the metallurgical boundary of the p-n junction along the thickness of the layer (1);

q—an elementary charge;

Ni(x,h,z)—dopant profile in the layer (1);

∈ₛ—permeability of the layer (1);

d(x,z)—the thickness of the layer (1)

z, x—the coordinates on the surface of the layer (1);

Uk—built in junction potential of the layer (1).

In addition the semiconductor device may be characterized in that the contact strips are established on the insulating layer (13) being formed on the outer surface of the device and are provided to the ohmic contacts. Besides, the deice may be characterized in that the semiconductor layer is formed with a modulated dopant profile along the direction X primarily selected on the surface of the layer (1), and conductor strips (3) are formed on the surface of the semiconductor layer (1) along the other direction Z, said strips forming an ohmic contact with the layer (1) and are arranged in a spaced relation to the ohmic contact. In addition, the semiconductor device may be characterized in that another dielectric layer (9) (high-ohmic semiconductor layer) is formed over the free surface of the device (any area of the surface except for the contact parts and conducting strips aimed at connecting the device with outer units).

Hence, the essence of the present invention resides in that a possibility is provided for changing the capacitance of conductance effective between the ohmic contact with the semiconductor layer (1) and a conductor layer established on the insulating or low-conductivity layer by means of supply voltage applied to p-n junction in a wide range.

### BRIEF DESCRIPTION OF THE DRAWINGS

In what follows the present invention is exemplified by the disclosure of some specific embodiments thereof to be had in conjunction with the accompanying drawings wherein:

FIG. 1 presents one of the embodiments of the herein proposed semiconductor device;

FIG. 2 presents one of the embodiments of the semiconductor device;

FIG. 3 presents the absence of the surface layer depletion by the basic charge carriers at the boundary between isolating layer performed as dielectric and the semiconductor layer (1);

FIG. 4 presents one of the embodiments of the semiconductor device;

FIG. 5 presents one of the embodiments of the semiconductor device;

FIG. 6 presents one of the structures of the semiconductor device;

FIG. 7 presents one of the embodiments of the semiconductor device comprising transistor structure;

FIG. 8 presents one of the embodiments of the semiconductor device comprising a source of control voltage and a source of input signal;

FIG. 9 presents the construction of a transistor;

FIG. 10 presents the proposed semiconductor device comprising contact areas;

FIG. 11 presents one of the embodiments of the semiconductor device comprising conducing strips and conducting areas;

FIG. 12 presents on of the embodiments of the proposed semiconductor device;

FIG. 13 presents one of the embodiments of the proposed semiconductor device comprising a safety layer;

FIG. 14 presents a schematic embodiment of the proposed semiconductor device;

FIG. 15 presents a graphic representation of a relationship between a modified capacity and voltage in case if the isolating or low-conductivity layer is made of dielectric and set along A line, a graphic representation of a relationship between modified capacity and voltage in case of if the isolating or low-conductivity layer is partially made of dielectric except for the area made of high-ohmic conductor contacting with the layer (1) along B line.

To illustrate the operation of the proposed device it is necessary to mention that the condition of the fully depletion of the layer (1) or parts of said layer by means of the charge carriers till the breakdown of the p-n junction and/or Schottky barrier upon applying thereto an external bias voltage determined for a prototype:

$$( q / {ε}_{s} ) \cdot {\int }_{0}^{d ( x , y )} Ni ( x , y , z ) y ⅆ y - Uk < Ui$$

where Ui—the breakdown voltage of the semiconductor layer (1);

y—the coordinate counted off the metallurgical boundary of the p-n junction or Schottky barrier along the thickness of the layer (1);

q—an elementary charge;

Ni(x,y,z)—dopant profile in the layer (1);

d(x,z)—the thickness of the layer (1);

z, x—the coordinates on the surface of the film;

∈ₛ—dielectric permeability of the layer (1);

Uk—built-in potential.

The above-mentioned inequality is certain till the fully depletion of the area of the semiconductor layer (1) by means of movable charge carriers.

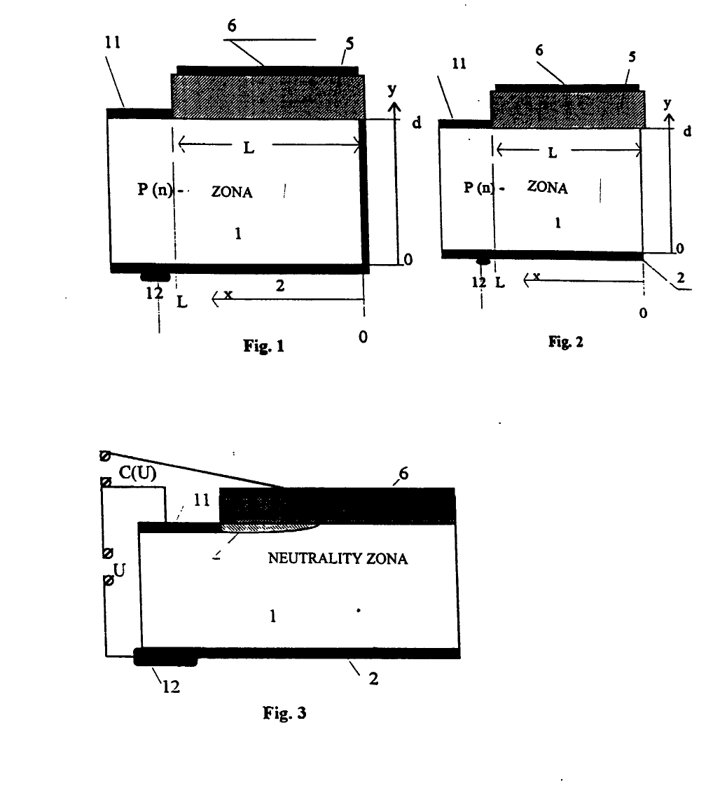

It is noteworthy that to fully depletion of the semiconductor layer (1) or to creating capacitance manageable by means of voltage or wide-range values of capacitance (of resistance) said condition is necessary but not sufficient. FIG. 1 illustrates an embodiment of the semiconductor device appeared as a device comprising semiconductor layer (1) having a hole-type conductivity and provided to the first ohmic contact (11), said contact mounted on the upper surface of the said semiconductor layer (1) while the other part of the upper surface having insulating layer (5) on which surface the conduction area (6) is formed, the other layer (2) is formed on the lower right side surface of the semiconductor layer (1) with ohmic contact (12), said layer (2) (to make it clearer in this very case) is effected as Schottky contact. To make it clear and to avoid breaking of community of the reasoning a flat task is being under consideration (Ni(x,y,z)=Ni(x,y)). It is supposed that E_{y}—a normal component of the electric field to the surface of the insulating layer; Ex—a component of the electric field set along a tangent to the surface of insulating layer: p—the concentration of holes; n—the concentration of electrons under condition that Ey=const in semiconductor area on the boarder of partition between the semiconductor layer (1) and the insulating layer (which corresponds to the supply of constant voltage as well as zero voltage between the ohmic contact to the semiconductor layer (1) and a contact (conduction area) set on the insulating layer) Poisson's equality at the surface dEₓ/dx+dE_{y}/dy=q/∈ₛ(−Ni(x,y)+p−n) can be transformed to the equality as follows:

dEₓ/dx=q/∈s(−Ni(x,y)−n+p) (1)

As Eₓ∝dφ/dx out of (1) under fully depletion of P-area on the boundary between insulating layer and p-area (n,p<<Ni(x,y)), said (1) appears as follows:

d²φ/dx²=q/∈ₛNi in condition that y=d, 0≦x≦L

Where φ—potential,

L—the size of the semiconductor layer (1) set under insulating layer along direction x.

After solving this equality under conditions that φ(0,d)=0 and dφ(x, d)/dx=0 the following expressions appear:

$$φ ( x , d ) = {\int }_{0}^{x} ( q / {ε }_{s} ) Ni ( h , d ) h ⅆ h ; φ ( L , d ) = {\int }_{0}^{L} ( q / {ε }_{s} ) Ni ( h , d ) h ⅆ h ;$$

Here φ(L,d) is a minimum value of voltage between the contacts under which the depletion of the p—area on the boundary between insulating surface and p—area by means of movable charge carriers is performed.

φ(L,d) comprises built-in potential, Uk—voltage value on the semiconductor layer (1) in condition of external bias voltage absence.

In conditions that L>>d and inside p-area under depletion N(x,y)>>n,p it may be considered that the potential may change along y much more than along x and the Poisson's equality dEₓ/dx+dE_{y}/dy=q/∈ₛ(−Ni(x,y)+p−n) and taking into account that Eₓ∝−dφ/dx, E_{y}∝−dφ/dy appears as follows: d²φ/dy²=q/∈ₛ Ni(x,y) and under boundary conditions φ(x,0)=0, dφ(x,y)/dy=0 has the following solution:

$${φ}_{1} ( x , y ) = {\int }_{0}^{y} ( q / ε s ) Ni ( x , h ) h ⅆ h ; {φ}_{1} ( x , d ) = {\int }_{0}^{d} ( q / ε s ) Ni ( x , h ) h ⅆ h$$

In a three-dimension case the solution appears as follows:

$${φ}_{1} ( x , y , z ) = {\int }_{0}^{y} ( q / {ε }_{s} ) Ni ( x , h , z ) h ⅆ h ;$$

$${φ}_{1} ( x , y , z ) = {\int }_{0}^{d} ( q / {ε }_{s} ) Ni ( x , h , z ) h ⅆ h$$

Here φ₁(x,d), (φ(x,d,z))=the minimum value of the voltage between the contacts under said value the depletion of p-area in the capacity to x(x,z) section under condition of 0<y<d is effected.

Under the absence of the layer (2) on the right side surface of the semiconductor layer (1) (see FIG. 2 illustrating the semiconductor device comprising semiconductor layer (1) which for clarification appeared as hole-type conductivity with the first ohmic contact (11) effected on the part of the upper surface of the said semiconductor layer (1), while on the other part of the upper surface an insulating layer (5) is formed; on said insulating layer (5) surface a conduction area (6), another layer (2) formed on the lower surface of the semiconductor layer (1) with ohmic contact (12) (said layer (2) for clarification in this particular case is effected as Schottky contact). The minimum value of the voltage between the contacts under which fully depletion of the p-area and the boundary between insulating layer and p-area is effected, φ(L,d) may appear as the following correlation:

$$φ ( L , d ) = {\int }_{0}^{L} ( q / ε s ) Ni ( h , d ) h ⅆ h + {\int }_{0}^{d} ( q / {ε }_{s} ) Ni ( 0 , h ) h ⅆ h$$

In a three-dimension case the minimum value of the voltage between the contacts under which fully depletion of p-area at the boundary between insulating layer and p-area is effected, φ(L,d) can be expressed by the following correlation:

$$\begin{matrix}φ ( L , d , z ) = {\int }_{0}^{L} ( q / ε s ) Ni ( h , d , z ) h ⅆ h + \\ {\int }_{0}^{d} ( q / ε s ) Ni ( 0 , h , z ) h ⅆ h\end{matrix} \qquad ( 2 )$$

In a common case L appears as a function of the coordinate z(L=L(z)), whereas d may appear as a function of both x and z (d=d(x,z)).

If φ₁(x,d,z)<Uk+Ui and φ(L,d,z)<Uk+Ui under conditions of outer voltage U and considering U+Uk≧φ₁(x,d,z), U+Uk≧φ(L,d,z) an area of spatial charge (ASC) is spread over the whole capacity of the semiconductor layer (1).

If φ₁(x,d,z)<Uₖ+Uᵢ and φ(L,d,z)>Uk+Ui then in conditions of external voltage U in case of the inequality φ(L,d,z)≧U+Uk≧φ₁(x,d,z)−Uk the ASC may be spread over the capacity of semiconductor layer (1) except for the upper surface of the said semiconductor layer which part boundaries between insulating layer and the contact is not being depleted. FIG. 3 illustrates the absence of the depletion of the surface by means of movable charge carriers in conditions of capacity depletion, on which the presented semiconductor device is mounted, said device comprising semiconductor layer (10 for clarification appearing as the layer with hole-type conductivity with the first ohmic contact (11) effected on the part of the upper surface of the said semiconductor layer (1). On the other part of the upper surface a insulating area (5) is formed on which surface conduction area (6) is formed, whereas the other layer (2) being formed on the lower surface of the semiconductor layer (1) with ohmic contact (12), external bias is provided between ohmic contacts (11) and (12). Neutral zone exists near the boundary between the semiconductor layer (1) and insulating layer (5) under any external bias U(U<Ui). Said existence is confirmed by both calculations under diffusion—drift approximation and experimental data received upon the measurements of p-n junction capacity and manageable capacity C(U), which is a capacity formed between ohmic contact to the semiconductor layer (1) and conduction area on insulating layer.

To create a manageable capacity (manageable resistance) in rely to wide range in changing of the managing diapason it is necessary that L>d in conditions of the surface depletion effect. Otherwise said diapason would not be in the wide range. Nevertheless in case of L>d if special measures on the implementation of the boundary between the semiconductor layer (1) and insulating layer made of high-ohmic semiconductor material are not taken, then φ₁(x,d,z)<φ(L,d,z) and Ui<φ(L,d,z). In this case, depletion of the surface of the semiconductor layer (1) is not effected. The depletion of the surface by means of charge carriers is effected in case if p-n junction between insulating layer and the semiconductor layer (1) is formed as a result of high-ohmic area of spatial charge in the semiconductor layer (1) and in conditions of the contacting area being made of high-ohmic (lightly alloyed) semiconductor material (Ni(x,d,z)→0 and the first item can be neglected) and the condition of depletion of the layer (1) by means of the majority of charge carriers till the breakdown of the p-n junction including that appeared as hetero-junction external bias being applied to this junction, said condition appears as follows:

$${\int }_{0}^{d ( x , z )} ( q / {ε }_{s} ) Ni ( x , h , z ) h ⅆ h - Uk < Ui$$

The conditions of the depletion of the surface are not connected with the location of the layer (6) in rely to the layer (1). That means that the ability of the device to operate does not depend on the location of the layers (1) and (6) on the insulating layer as well as on the said insulation layer shape. So if the layer (5) has its outer surface on one part of which (one surface) the layer (1) is set while on the other part (other surface) the layer (6) is formed; between layers (1) and (6) there is a free part of outer surface of the layer (5). It is noteworthy that p-n junction effected by layers (1) and (2) may appear comprising both a homogeneously alloyed layer (1) and non-homogeneously alloyed along X(Z) layer (2). For clarification in these examples, the layer (1) is formed with hole-type conductivity. It is evident that semiconductor layer (1) may appear with electron-type conductivity; in this case the layer (2) should be made of either semiconductor of the hole-type or a metal forming p-n junction or Schottky barrier or semiconductor forming p-n junction with the layer (1) due to the difference in sizes of the energetic zones of the layers (1) and (2). Besides, the layer (5) may be made either of a semiconductor forming p-n junction and/or Schottky barrier with the layer (6) or of semi-insulation semiconductor. Evidently, the thickness of the layer (1) may be both homogeneous and non-homogeneous. The area (2) being made of a semiconductor may be alloyed both homogeneously and non-homogeneously along X(Z), where X and Z—are different directions in the flatness of the layer (1) surface, including curvilinear ones. To reduce the connection between capacities between (2) and (6) common depletion of the areas (1) and (2) should be provided by means of main charge carriers under voltage supply by means of approximately equal alloy of the areas (1) and (2). Evidently the barrier between the surface of the layer (1) and the layer (2) may be formed in a constitutive way (i.e. p-n junction may be formed on the part of the layer (1) while Schottky barrier may be formed on the other part of that surface) while p-n junction formed between (1) and (2) may appear as hetero-junction. In a common case, dielectric permeability of a semiconductor may appear as a function of coordinates, so es is put under the sign of integral.

To clarify the terminology used in the present invention it is noteworthy that the insulating layer—is a layer which resistance between (1) and (6) is high enough, it is correlative to that of the insulator or insulating p-n junction. The inner embodiment and the shape of the insulating layer may be chosen at will. For example insulating layer may comprise conducting areas not connecting those areas of the layer surface where (1) and (6) are formed. Any material including dielectric has its conductivity under direct current. That means that the same material can be considered both insulating and conducting (low-conductivity) depending on the signal frequency. An doping profile Ni(x.h.z) is understood to appear as a capacitance concentration of ionized dopings. I.e., for example, under conditions of Nd(x,h,z)>Na(x,h,z) and Ni(x,h,z)=Nd(x,h,z)−Na(x,h,z), where Nd(x,h,z) is a concentration of fine donor doping, Na(x,h,z)—concentration of acceptor doping (including deep acceptors). An area of the insulating layer (14) contacting with the semiconductor layer (1) formed of high-ohmic semiconductor due to contacting strip being made of high-ohmic semiconductor or due to p-n junction formed between the insulating layer and the semiconductor layer (1), i.e. an area of the layer (5) having common boundary with the layer (1) formed by means of a semiconductor having high specific resistance (i.e. that it having low concentration of free charge carriers). In its turn the layer (1) having an area of its outer surface common to that of the layer (2) and the other part of the outer surface common to the contacting strip of the layer (5 (14)). A free surface of the device is considered any area of the outer surface of the said device except for any parts of contacts or parts of conducting strips necessary for connection to external devices. In case of the device appeared as comprising contact area latter is not considered an outer surface of the device. Contact areas are meant to be parts of the contacts aimed at connecting the device to capacity conductors connecting the device with external devices (power sources, loads, other elements of the scheme comprising semiconductor device). A p-n junction is understood to be an area of a spatial charge (ASC) in a semiconductor adjoining the boundary between either a metal and a semiconductor or between two semiconductors (with difference in energetic zone sizes) or between two areas of a semiconductor having different values or types of electric conductivity (cf. “Electronics” encyclopedic dictionary, Moscow Sovetskaya Encyclopedia, 1991, page 419). Built-in potential of p-n junction is considered to appear as a potential between ohmic contacts to p-n junction in conditions of the absence of external bias. Built-in potential of the layer (1) Uk appears as a part of a built-in potential of the p-n junction formed on the layer (1).

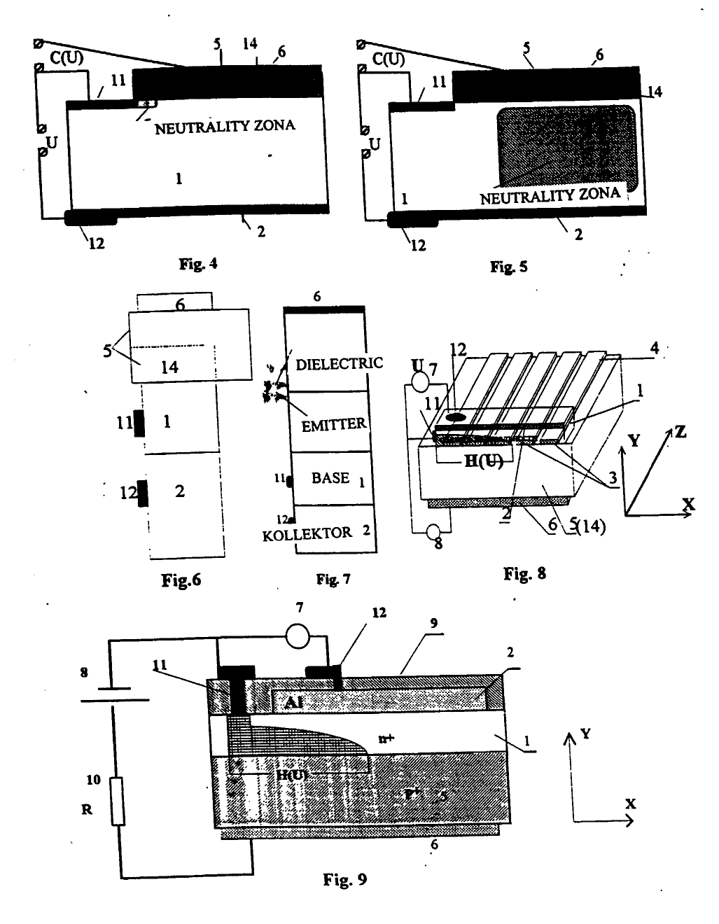

The primary object of the present invention can be accomplished without standing the condition of the fully depletion of the whole capacity of the semiconductor layer (1). If the condition of surface depletion is stood—an area contacting with the semiconductor layer (1) formed of high-ohmic semiconductor due to either contacting strip being made of high-ohmic semiconductor material or p-n junction being formed between the insulating layer and semiconductor layer (1); under said conditions wide range in changes of the manageable capacity or the manageable resistance can be achieved under capacitive depletion of a part of the capacity of the semiconductor layer (1) by means of main charge carriers. FIG. 4 and FIG. 5 present manageable capacitor appeared as a device comprising the semi conduction layer (1) for clarification appearing with hole-type conductivity with the first ohmic contact (100) established on a part of the upper surface of said semiconductor layer (1). On the other part of the upper surface an insulating layer (5) is formed; said layer (5) comprises high-ohmic semiconductor layer boundaries with the layer (1), conducting strip (6) is formed on the upper surface of the layer (5) as well as the second layer (2) having common surface with semiconductor layer (1) and ohmic contact (12). External bias being provided between ohmic contacts (11) and (12). FIG. 4 illustrates a semiconductor device where the main area of the semiconductor layer (1) is depleted under supply of managing voltage. FIG. 5 illustrates an embodiment of manageable capacitor where an area of the semiconductor layer (1) between ohmic contact to the semiconductor layer (1) and layer (2) is depleted by means of managing voltage supply. In both cases, manageable capacity may vary in wide range of values.

FIG. 6 presents a schematic device of a manageable capacity comprising layers (2.1.5.6) consequently formed one by one as well as ohmic contacts (11) to layer (1) and (12) to layer (2) while layer (14) is a highly ohmic semiconductor layer ((14)—is a part of layer (5) and boundaries with (1)). Layer (2) is formed of semiconductor of n(p) type of conductivity or of a metal forming Schottky contact with layer (1). Layer (1) is formed of semiconductor of p (n) type of conductivity, while layer (6) is formed of conducting material, a part of layer (5) (except for (14)) may be formed of any kind of material.

FIG. 7 presents a device appearing as a transistor in which layer (1) is a base formed of a semiconductor of n (p) type of conductivity, layer (2) appears as a collector formed of a semiconductor of p(n) type or a metal forming p-n junction or Schottky barrier with layer (1); layer (5) comprising an emitter made of a semiconductor of p(n) type or a metal forming Schottky contact with (1) (in this very case (14) appears as ASC between the emitter and the base). On the surface of the emitter a layer of dielectric is formed on said dielectric layer a conducting strip (6) is based, layers (2,1,4,5) are formed in sequence one on one, at least two of the layers comprising ohmic contacts (11) to layer (1) and (12) to layer (2). Such structure may appear comprising a common ohmic contact for emitter and collector (emitter is equipped with ohmic contact connected to collector by means of ohmic contact).

The ability to operate in all the cases is evident: under supply of managing voltage to p-n junction set between (1) and (2) the size of neutral zone of (1) changes due to which capacity between the neutral zone and (6) changes as well. Or if (5) is formed of low-conductor material is formed the value of resistance between (1) and (6) also changes in case if the value of resistance in the area (5) is less that the value of capacitance resistance, otherwise the device operates as manageable by means of voltage capacity with low-conductor layer (5). The depletion of the surface by means of charge carriers is effected due to either the p-n junction formed between insulating layer and the semiconductor layer (1) or due to contacting strip being made of high-ohmic material. If the value of voltage of overlapping Up (a minimum external voltage value under which a capacitance depletion of an area or of the whole layer (1) is effected by means of charge carriers) is less than the value of the voltage of breakout, the following inequality is valid:

$$Up = {\int }_{0}^{d ( x , z )} ( q / {ε }_{s} ) Ni ( x , h , z ) h ⅆ h - Uk < Ui$$

than external voltage exists U>Up while U<Ui under which capacitance and surface depletion of the layer (1) is effected by means of charge carriers.

The above-mentioned devices (FIGS. 4,5,6,7) on their free surface may comprise insulation layer (9) (which resistance between conducting parts of the device can be compared to the resistance of isolator or insulating semiconductor) formed to prevent the device from the dust as well as to separate the device from other elements of the scheme comprising the device if effected in integral embodiment. The shape of layer (5) and relative position of layers (6) and (1) on layer (5) may be chosen at will.

To clarify the operation of the device offered in this invention comprising conducting strips FIG. 8 presents one of the embodiments of the device comprising area (1) of n(p) type, which is non-homogeneously alloyed along X direction, with ohmic contact (11), area (2) with ohmic contact (12) forming p-n junction or Schottky barrier with area (1), conducting strips (3) provided to conducting strips (4), an insulating layer (5), conducting strip (6). FIG. 6 presents a source of managing voltage (7) connected with p-n junction, a source of external signal (8). An insulating layer (5 (14)) is made of high-ohmic semiconductor material with I-type of conductivity. Whereas the value of overlapping voltage of the semiconductor layer (1) (a minimum value of external voltage on layer (1) under which capacitance depletion of the layer (1) is effected by means of charge carriers) is less than that of breakout voltage.

On conducting strips (3) semiconductor layer (1) of n- or p-type of conductivity is formed which forms ohmic contact with said strips. Layer (1) is being non-homogeneously alloyed along X direction. The level of alloy is being reduced in relation to the increase of X. On layer (1) an area (2) is formed with ohmic contact forming p-n junction with the layer (1). In relation with increasing of cutoff voltage U (source 7) at the junction the size of neutral area is constantly decreasing along X direction in the semiconductor of n− type of conductivity (H(U)). In this case an effective width of capacitor plates W with discreetness equal to the width of area (3) conforms to H(U) thus leading to proportional reduce in capacitance between (6) and ohmic contact to area (1) (C˜H(U)). Layer (5) being formed of high-ohmic semiconductor allows standing the condition of the depletion of the surface and realization of maximum range of changes in capacitance both p-n junction and manageable capacitance between contact (11) and conducting strip (6). It is noteworthy that layer (5) (or a part of that layer (5) contacting with the semiconductor layer (1)) may be formed of a semiconductor with the opposite type of conductivity in response to the layer (1). In a common case to stand the condition of the depletion of a surface it is necessary that a part of insulating layer contacting with the semiconductor layer (1) should be formed of high-ohmic semiconductor. Because of contacting strip being formed of high-ohmic semiconductor material or because of formation of p-n junction between insulating layer and semiconductor layer (1). The presence of conducting strips allows the device to be used as a transmission line with a changeable wave resistance. The width of line W with discreetness equal to the width of one of the strips (3) conforms to H(U) thus leading to a proportional increase in a wave resistance of a line (ρ˜1/H(U)). On the free surface of the device an insulating layer (9) may be formed. The shape of layer (5) and disposition of layers (6) and (1) on layer (5) may be chosen at will.

Method to avoid undesirable influence of capacity connection between areas (6) and (2) consists in that in p-n junction both p-area and n-area are alloyed non-homogeneously along Z(X). While in case of increasing in managing voltage the size of neutral area along Z(X) decreases accordingly to that in n-area.

A semiconductor device now is considered to operate as transistor. In this case, layer (5) should appear as a conductor. In this very case layer (5) is made of highly alloyed p+ type of a semiconductor material forming a tunnel p-n junction with layer (1). To clarify the operation of the proposed device see FIG. 9 presenting a transistor comprising p+ type of conductivity of layer (1), which is alloyed non homogeneously along X direction, with an ohmic contact (11), area (2) with an ohmic contact forming Schottky barrier with area (1) and low-conductivity layer (5) of p+ type. FIG. 7 presents a source of managing voltage (7) applied to p-n junction, a source of direct voltage (8). The layer (1) is alloyed non-homogeneously along the direction of X. The ratio of alloy being decreased accordingly to increase in X. On layer (1) area (2) with ohmic contact is formed, which forms Schottky barrier with area (1). In accordance with increase in cutoff voltage U (source 7) at the junction the size of neutral area of n-type (H(U)) along X constantly decreases. An effective width of the contact between areas (1) and (5) conforms to H(U). Thus value of output resistance of a transistor is being changed, said output resistance is inversely proportional to the effective area of ohmic contact.

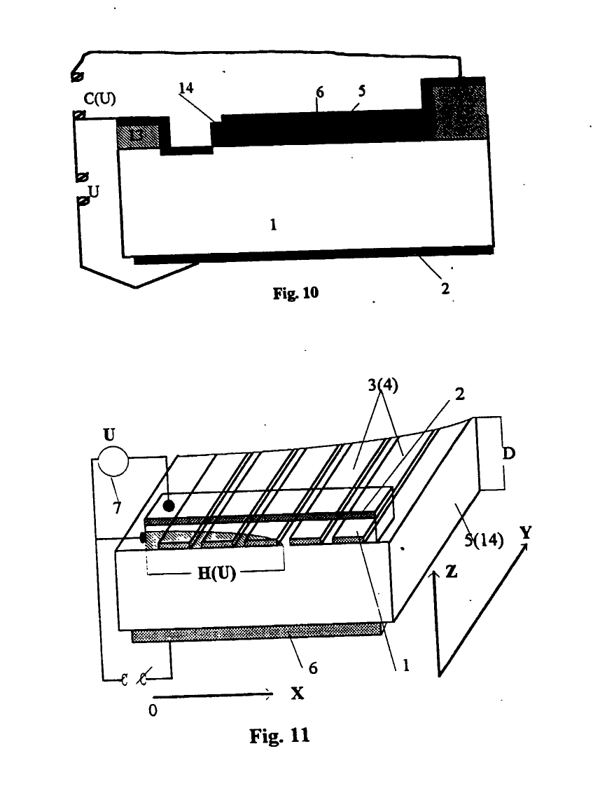

In microelectronics when semiconductor devices appear as a device in discreet embodiment contact strips as a rule are formed on isolating layer. FIG. 10 presents a semiconductor device comprising layers (2,1,5,6,) formed in sequence one on each other and insulting layer (13) on which contact strips are formed being connected with external conductors. Layers (1) and (2) being equipped with ohmic contacts. On the free surface of the presented device an insulating layer (9) may be formed. The shape of the layer (5) and disposition of layers (6) and (1) on layer (5) may be at will. A part of the layer (5 (14)) contacting with (1) is made of high-ohmic semiconductor.

A manageable capacitor is being under consideration. Said capacitor comprising p-n junction (Schottky barrier) with non-homogeneous alloy profile along X direction. Said p-n junction comprising area (2) of p(n) type with ohmic contact on which a film is formed; said film is of n(p) type of conductivity with ohmic contact formed on conducting strips (3). Conducting strips are formed on the surface of layer (5) made of high-ohmic conductor. On the surface (5) a metal layer (6) is formed (FIG. 11). Conducting strips are formed on the operating section (0≦x≦Xmax, 0≦z≦F(x)). In said film by means of ionic alloy a non-homogeneous profile of doping Ni(x,y) is formed, implantation dose being increased from Xmax to 0. While increasing of cutoff voltage at the junction an area of spatial charge (ASC) gradually is filling an operation area of the film, thus the size of neutral area H(U) and the effective area of the plates of manageable capacitor formed between conducting strips (3) and metal layer (2) are constantly decreasing. P-n junction (Schottky barrier) is formed over negligible part of area (3) (beyond p-n junction in accordance to the accepted terminology said strips are called areas (4)). By means of choosing of the size of operating area F(x) a necessary relation of capacity to voltage can be provided. It is noteworthy that conducting strips (4) can have shapes different from the rectangular one.

FIG. 12 presents a manageable capacitor comprising p-n junction (Schottky barrier) with non-homogeneous doping profile along direction X. On the surface of p-n junction (Schottky barrier) an insulating layer is formed, said layer is made of high-ohmic (semi-insulating) semiconductor on which surface a conducting layer (6) is formed. P-n junction comprising an area (2) of p− type with ohmic contact on said area a film of n-type is formed with other ohmic contact. In the area (2) a non-homogeneous profile of accept doping Na(x,y) is formed, the rate of doping being reduced from Xmax to 0. In the area of light doping, the ASC penetrates into area (2) deeper and it penetrates into less thickness into the film (1) (including homogeneously doped). As cutoff voltage increases at the junction area of spatial charge (ASC) gradually fills the whole film thus the size of neutral area H(U) and effective size of plates of manageable capacitor formed between the neutral area of the film and the metal layer (6) are constantly decreasing. Evidently, the area (2) may be of n-type of conductivity if area (1) appears to be with hole-type conductivity.

It is noteworthy that in case of direct connection or disconnection of areas (2) and (6) a semiconductor device appeared as a manageable capacity may be used as varicap.

In case if semiconductor devices appear in a discreet embodiment the whole surface of the device is usually by insulating layer (9) except for contact strips (most often this layer is formed of resist or silicon dioxide), which relies to the proposed devices. In case if the semiconductor device appears as integral device its contact strips are absent and the whole surface of the device or its part necessary for protection is covered with protecting layer. An insulating (protecting) layer (9) fulfils the function of protection from dust and from breakout on the surface.

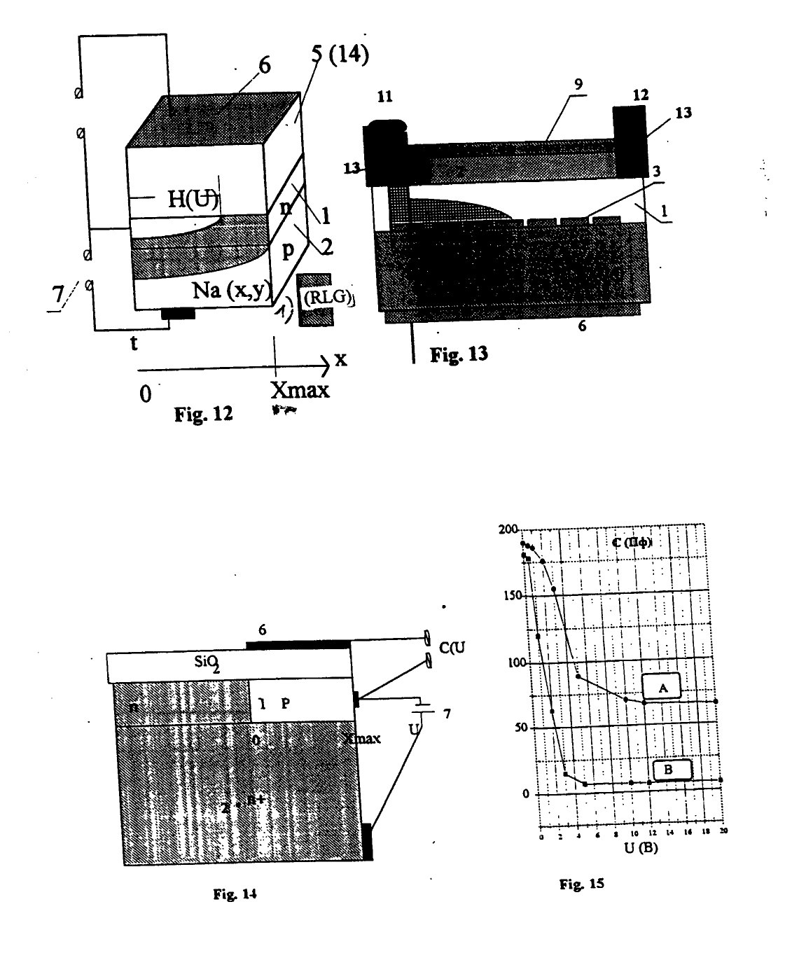

As an example FIG. 13 presents one of the embodiments of semiconductor device comprising layer (1) doped non homogeneously and comprising area (1) of n(p) type of conductivity being doped non homogeneously along X direction with an ohmic contact (11), area (2) with an ohmic contact (12) forming either p-n junction or Schottky barrier with area (1), conducting strips (3), an insulating layer (5), conducting strip (6). FIG. 13 presents protecting insulating layer (9) and layer (13) being insulating one, on said layer contact strips are formed. Contacting with (1) part of insulating layer (5 (14)) is made of high-ohmic semiconductor. The voltage of overlapping of the semiconductor layer (1) (minimum value of voltage on layer (1) under which depletion of capacity of layer (1) by means of charge carriers is effected) of the semiconductor layer (1) is less than its breakout voltage. On conducting strips (3) layer (1) of either n-type or p-type is formed, said layer forming ohmic contact with strips (3). Layer (1) is being doped non-homogeneously along X direction. The level of doping being reduced in accordance with increase in X. On layer (1) area (2) with ohmic contact is formed, said area (2) forming p-n junction with area (1). The fact that (14) is made of high-ohmic semiconductor makes it possible to stand the condition of the depletion of the surface and to fulfill the maximum range in change of capacity of both p-n junction and manageable capacity between contact (110 and conducting strip (6). It is noteworthy that layer (5) may be made of a semiconductor of the opposite type of conductivity in relation to layer (1). The disposition of strips (3) along direction crossing direction X makes it possible to use the device as a transmission line with changes in its length and discreetness equal to the width of strip (3). The shape and relative disposition of layers (6) and (1) on layer (5) may be chosen at will.

One of the advantages of manageable capacity is that it is characterized in absence of the so called electron limit which is connected with electric breakout of the semiconductor by means of power and limits applying to the sizes of operation area of the semiconductor device by means of velocity of charge carriers (great power may be taken off the manageable capacity including those on high frequencies under parametric strengthening of generation and frequency transforming). Nevertheless for practical use it is necessary to take into account the fact that a p-n junction is always formed in parallel with manageable capacity, said junction is in sequence connected with capacity formed between (6) and (2). To reduce voltage at p-n junction between (1) and (2) larger capacitance should be included in parallel way and/or the thickness of insulating layer should be increased.

### EXEMPLARY EMBODIMENTS OF THE INVENTION

On heavily doped layer of n+ type of conductivity a film is established having donor concentration of doping ˜10¹⁴ 1/cm³, 2 micrometers thick (d=2 micrometers). On the area of 1-mm² of said layer an acceptor doping profile 50-mm long being modulated along the width (X) from 1.5*10¹⁵ 1/cm³ until 0.3*10¹⁵ 1/cm³. Ohmic contacts were applied to p- and n-areas. On the surface of the film by means of thermal oxidation, a layer of silicon dioxide was established 0.2-mcm thick, on the surface of silicon dioxide a metal layer (6) was formed. FIG. 14 illustrates a schematic embodiment of the device, where (1)—layer of p-type,

(2)—layer with donor conductivity,

(6)—conducting area on silicon dioxide layer,

(11)—ohmic contact to (1),

(12)—ohmic contact to (2).

FIG. 14 presents a source of managing voltage connected with ohmic contacts (11) and (12). For a device presented in FIG. 12 having 1-mm² conducting area on shutting oxide L=2 mm, having cutoff voltage φ₁(x,d,z) of about 5 V, insulating layer (made of SiO₂) 0.2-mcm thick measurement of the value of manageable capacity has been effected. FIG. 13 presents an experimental relationship of manageable capacity to voltage C(U) (the capacity has been measured between ohmic contact (11) and conducting strip (6)). The value of the capacity between ohmic contact to the semiconductor layer (1) and conducting strip on insulating layer was calculated to be about 6*10⁻¹² farad. As shown in FIG. 15 (A curve) manageable capacity is much more than 6*10⁻¹² farad, which conforms the absence of the depletion of the layer.

On heavily doped layer of n+ type of conductivity a film is established having donor concentration of doping ˜10¹⁴ 1/cm³, 2 micrometers thick (d=2 micrometers). On the area of 1-mm² of said layer an acceptor doping profile 50-mm long being modulated along the width (X) from 1.5 1015 1/cm3 until 0.3 1015 1/cm3. Ohmic contacts were applied to p- and n-areas. On the surface of the film by means of thermal oxidation, a layer of silicon dioxide was established 0.2-mcm thick. A high-ohmic layer semiconductor layer 0.05-mcm thick is formed on the boundary between layer (1) and silicon dioxide by means if ion implantation. On the surface of silicon dioxide a metallic layer (6) is formed. A measurement of manageable capacity of the presented device in the area between an ohmic contact to layer (1) and conducting strip (6) was effected showing (B curve in FIG. 15) that in conditions of reverse voltage of about 6-10 V at p-n junction the value of manageable capacity striving for the calculated limit of about 6*10-12 farad. This confirms the presence of depletion of both the surface and capacity of the layer (1) by means of charge carriers.

The invention is instrumental in the provision of inertia less variable capacitors, varicaps, transistors and controllable transmission lines.

### INDUSTRIAL APPLICABILITY

The invention can find application in the electronic industry.

1. A semiconductor device comprising insulating layer on one of whose surfaces a conductor area is established, while on the other surface thereof a semiconductor layer (1) is formed, having either an electron- or a hole-type conduction and provided with an ohmic contact, said layer (1) being coated with a layer (2) which is made of a metal and/or a semiconductor having the type of conduction opposite to that of the layer (1), said layer (2) forming a p-n junction and/or a Schotky barrier together with the layer (1) and having another ohmic contact; the doped profile and the thickness of the layer (1) should meet the condition of a complete depletion of the layer (1) or part of thereof in the majority charge carriers till the breakdown of the p-n junction or of the Schottky barrier upon applying an external bias voltage determined by the following inequality:
$$( q / ε s ) \cdot {\int }_{0}^{d ( x , z )} Ni ( x , y , z ) y ⅆ y - Uk < Ui$$
where Ui—the breakdown voltage of the semiconductor layer (I)
y—the coordinate counted off the metallurgical boundary of the p-n junction or Schottky barrier along the thickness of the layer;
q—an elementary charge;
d(x,z)—the thickness of the layer (1);
Ni (x,y,z)—the doping profile in the layer (1)
z, x—the coordinates on the surface of the layer (1);
∈s—the permeability of the layer (1);
Uk—built-in junction potential.
CHARACTERIZED in that the part of insulating layer contacting with semiconductor layer (1) being formed of high-ohmic semiconductor, the doping profile and the thickness of the layer (1) should meet the condition of a complete depletion of the layer (1) or part of thereof in the majority charge carriers till the breakdown of the p-n junction or of the Schottky barrier upon applying an external bias voltage determined by the following inequality:
$$( {\int }_{0}^{d ( x , z )} q / ε s ) Ni ( x , h , z ) h ⅆ h - Uk < Ui$$
where Ui—the breakdown voltage of the semiconductor layer (I)
h—the coordinate counted off the metallurgical boundary of the p-n junction or Schottky barrier along the thickness of the layer;
q—an elementary charge;
d(x,z)—the thickness of the layer (1);
Ni (x,h,z)—the ion doping profile in the layer (1)
z, x—the coordinates on the surface of the layer (1);
∈s—the permeability of the layer (1);
Uk—built-in junction potential of the layer (1).

2. A semiconductor device as set forth in claim 1 CHARACTERIZED in that contacting strips are established on insulating layer formed on outer surface of the device and are connected to ohmic contacts.

3. A semiconductor device as set forth in claim 1 CHARACTERIZED in that the p-n junction is formed with a midified doping profile along X direction set on the surface of semiconductor layer (1), said surface having conducting strips formed along the other direction Z forming p-n junction contact to the semiconductor layer (1). The areas are arranged in a spaced relation to the ohmic contact of the layer (1).

4. A semiconductor device as set forth in claim 2 CHARACTERIZED in that the p-n junction is formed with a modified doping profile along X direction set on the surface of semiconductor layer (1), said surface having conducting strips formed along the other direction Z forming p-n junction contact to the semiconductor layer (1). The areas are arranged in a spaced relation to the ohmic contact of the layer (1).

5. A semiconductor device as set forth in claim 3 CHARACTERIZED in that conducting strips are arranged on one part of the surface of insulating layer are connected to conducting strips arranged on the other part of the surface of insulating layer.

6. A semiconductor device as set forth in claim 4 CHARACTERIZED in that conducting strips are arranged on one part of the surface of insulating layer are connected to conducting strips arranged on the other part of the surface of insulating layer.

7. A semiconductor device as set forth in claim 1 CHARACTERIZED in that an insulating layer is arranged on the free surface of the device.

8. A semiconductor device as set forth in claim 2 CHARACTERIZED in that an insulating layer is arranged on the free surface of the device.

9. A semiconductor device as set forth in claim 3 CHARACTERIZED in that an insulating layer is arranged on the free surface of the device.

10. A semiconductor device as set forth in claim 4 CHARACTERIZED in that an insulating layer is arranged on the free surface of the device.

11. A semiconductor device as set forth in claim 5 CHARACTERIZED in that an insulating layer is arranged on the free surface of the device.

12. A semiconductor device as set forth in claim 6 CHARACTERIZED in that an insulating layer is arranged on the free surface of the device.
